(19) United States
(12) Patent Application Publication
(10) Pub. No.: US 2024/0021515 A1
(43) Pub. Date: Jan. 18, 2024

(54) SEMICONDUCTOR STRUCTURE AND METHOD OF MANUFACTURING THEREOF

(71) Applicant: TAIWAN SEMICONDUCTOR MANUFACTURING COMPANY LTD., HSINCHU (TW)

(72) Inventors: HARRY-HAK-LAY CHUANG, Hsinchu County (TW); WEI-CHENG WU, Hsinchu county (TW); WEN-TUO HUANG, Tainan City (TW); YU-LING HSU, Tainan City (TW); PAI CHI CHOU, Taichung City (TW); YU-CHUN CHANG, Tainan City (TW); CHUNG-JEN HUANG, Tainan City (TW)

(21) Appl. No.: 17/812,700

(22) Filed: Jul. 14, 2022

(51) Int. Cl. H01L 23/522; H01L 23/00; H01L 25/065; H01L 23/528; H01L 23/31; H01L 21/56; H01L 21/768

(52) U.S. Cl. CPC H01L 23/5226; H01L 24/08; H01L 24/80; H01L 25/0657; H01L 23/5283; H01L 23/3171; H01L 23/3192; H01L 21/56; H01L 21/76832; H01L 21/76831; H01L 2224/80896; H01L 2224/80895; H01L 2224/08145; H01L 2924/37001; H01L 2225/06524; H01L 2225/06544

(57) ABSTRACT

The semiconductor structure includes a first die structure including a first substrate, a first bonding dielectric disposed over the first substrate, and a first bonding pad surrounded by the first bonding dielectric; a second die structure including a second substrate, an isolation member extending into the second substrate, a second bonding dielectric bonded with the first bonding dielectric, and a second bonding pad surrounded by the second bonding dielectric and bonded with the first bonding pad; a dielectric member disposed over the second die structure; a conductive via extending through the dielectric member, the second substrate and the isolation member; and a conductive member disposed over the dielectric member and at least partially in contact with the conductive via, wherein a first interface between the conductive via and the conductive member is substantially coplanar with a second interface between the conductive member and the dielectric member.

### BACKGROUND

The semiconductor industry has experienced rapid growth due to ongoing improvements in the integration density of a variety of electrical components. To accommodate the miniaturized scale of the semiconductor device, various technologies and applications have been developed for the wafer-level packaging, involving greater numbers of different components with different functions. Improvement in integration density has resulted from iterative reduction of minimum feature size, which allows more components to be integrated into a given area.

As semiconductor technologies further advance, stacked and bonded semiconductor devices have emerged as an effective alternative to further reduce the physical size of a semiconductor device. In a stacked semiconductor device, active circuits such as logic, memory, processor circuits and the like are fabricated at least partially on separate substrates and then physically and electrically bonded together in order to form a functional device. Such bonding processes utilize sophisticated techniques, and improvements are desired.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view of a semiconductor structure in accordance with some embodiments of the present disclosure.

FIG. 2 is a flow diagram of a method of manufacturing a semiconductor structure in accordance with some embodiments of the present disclosure.

FIGS. 3 to 15 are cross-sectional views of one or more stages of the method of manufacturing a semiconductor structure in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself indicate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although the terms such as “first,” “second” and “third” describe various elements, components, regions, layers and/or sections, these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies.

Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In the present disclosure, a semiconductor structure and a method of manufacturing a semiconductor structure are provided. The semiconductor structure includes a first die structure, a second die structure stacked and bonded over the first die structure, a conductive via extending at least partially through the second die structure, and a conductive member disposed over the second die structure and coupled with the conductive via. Other features and processes may also be included. In some embodiments, the method of manufacturing the semiconductor structure includes bonding a second die structure over a first die structure, forming a conductive via extending at least partially through the second die structure, and forming a conductive member disposed over the second die structure and coupled with the conductive via. Since the conductive member is directly in contact with the conductive via, additional connector (such as redistribution via at the backside (RVB)) between the conductive via and the conductive member and additional passivation layer (such as RVB film) between the conductive via and the conductive member are not required. Therefore, the manufacturing method is simplified and the manufacturing cost is thus reduced.

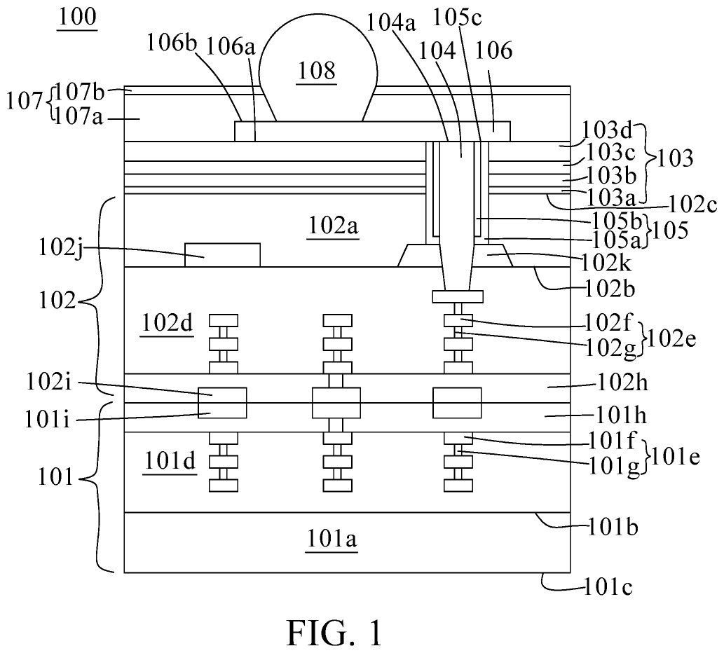

FIG. 1 is a schematic cross-sectional view of a semiconductor structure 100 in accordance with some embodiments of the present disclosure. In some embodiments, the first semiconductor structure 100 includes a first die structure 101, a second die structure 102 bonded over the first die structure 101, a dielectric member 103 disposed over the second die structure 102, a conductive via 104 extending through the dielectric member and partially through the second die structure 102, a conductive member 106 disposed over the dielectric member 103 and coupled with the conductive via 104, and a passivation 106 disposed over the dielectric member 103 and at least partially covering the conductive member 106. In some embodiments, the semiconductor structure 100 is a bonded structure or a part of the bonded structure. In some embodiments, the semiconductor structure 100 is a wafer on wafer (WoW) structure or a part of the WoW structure.

In some embodiments, the first die structure 101 is a chip, a package or a part of the chip or the package. In some embodiments, the first die structure 101 is a logic die, a central processing unit (CPU) die, a micro control unit (MCU) die, an input-output (IO) die, an application processor (AP) die, or the like. In some embodiments, the first die structure 101 includes a first substrate 101a, a first dielectric 101d disposed over the first substrate 101a, a first interconnect structure 101e disposed within the first dielectric 101d, a first bonding dielectric 101h disposed over the first dielectric 101d, and a first bonding pad 101i surrounded by and partially exposed through the first bonding dielectric 101h.

In some embodiments, the first substrate 101a includes semiconductive material such as silicon, germanium, gallium, arsenic, or a combination thereof. In some embodiments, the first substrate 101a is a semiconductor wafer. In some embodiments, the first substrate 101a is a silicon substrate. In some embodiments, the first substrate 101a includes a first surface 101b and a second surface 101c opposite to the first surface 101b. In some embodiments, the first surface 101b is a front side or an active side that several electrical components are disposed thereon. In some embodiments, the second surface 101c is a back side or an inactive side that electrical component disposed thereon is absent.

In some embodiments, the first dielectric 101d is disposed over the first substrate 101a. In some embodiments, the first dielectric 101d is disposed on the first surface 101b of the first substrate 101a. In some embodiments, the first dielectric 101d includes dielectric material such as polymer, polyimide, polybenzoxazole (PBO) or the like. In some embodiments, the first dielectric 101d includes several dielectric layers stacking over each other. In some embodiments, the dielectric layers includes same material or different materials. In some embodiments, the first dielectric 101d is interlayer dielectric (ILD).

In some embodiments, the first interconnect structure 101e is disposed within the first dielectric 101d. In some embodiments, the first interconnect structure 101e is an electrical routing within the first die structure 101. In some embodiments, the first interconnect structure 101e is electrically connected to a circuitry or an electrical component on or in the first substrate 101a. In some embodiments, the first interconnect structure 101e extends between the first substrate 101a and the first bonding dielectric 101h. In some embodiments, the first interconnect structure 101e includes conductive material such as copper, silver or the like.

In some embodiments, the first interconnect structure 101e includes a first pad portion 101f and a first via portion 11g coupled with the first pad portion 101f. In some embodiments, the first via portion 101g extends vertically within the first dielectric 101d. In some embodiments, the first pad portion 101f extends laterally within the first dielectric 101d. In some embodiments, the first pad portion 101f is coupled with a circuitry or an electrical component on or in the first substrate 101a. In some embodiments, the first pad portion 101f is at least partially exposed through the first dielectric 101d. In some embodiments, the first pad portion 101f and the first via portion 101g include conductive material such as copper, silver or the like.

In some embodiments, the first bonding dielectric 101h is disposed over the first substrate 101a. In some embodiments, the first bonding dielectric 101h is disposed over the first dielectric 101d. In some embodiments, the first bonding dielectric 101h is disposed over the first interconnect structure 101e. In some embodiments, the first interconnect structure 101e is at least partially exposed through the first bonding dielectric 101h. In some embodiments, the first pad portion 101f is at least partially exposed through the first bonding dielectric 101h. In some embodiments, the first bonding dielectric 101h includes dielectric material such as oxide or the like. In some embodiments, the first bonding dielectric 101h includes silicon oxide.

In some embodiments, the first bonding pad 101i is surrounded by and at least partially exposed through the first bonding dielectric 101h. In some embodiments, the first bonding pad 101i is electrically connected with the first interconnect structure 101e. In some embodiments, the first bonding pad 101i extends through the first dielectric 101h to electrically connect to the first interconnect structure 101e and the first substrate 101a. In some embodiments, the first bonding pad 101i is at least partially exposed through the first bonding dielectric 101h and configured to receive an external interconnect structure. In some embodiments, the first bonding pad 101i includes conductive material such as copper, silver or the like.

In some embodiments, the second die structure 102 is bonded over the first die structure 101. In some embodiments, the second die structure 102 is bonded over the first die structure 101 by any suitable bonding techniques such as hybrid bonding. In some embodiments, the second die structure 102 is a chip, a package or a part of the chip or the package. In some embodiments, the second die structure 102 is a logic die, a central processing unit (CPU) die, a micro control unit (MCU) die, an input-output (IO) die, an application processor (AP) die, or the like. In some embodiments, the second die structure 102 includes a second substrate 102a, a second dielectric 102d disposed over the second substrate 102a, a second interconnect structure 102e disposed within the second dielectric 102d, a second bonding dielectric 102h disposed over the second dielectric 102d, and a second bonding pad 102i surrounded by and partially exposed through the second bonding dielectric 102h.

In some embodiments, the second bonding dielectric 102h is disposed over the first die structure 101. In some embodiments, the second bonding dielectric 102h is disposed on the first bonding dielectric 101h. In some embodiments, the second bonding dielectric 102h includes dielectric material such as oxide or the like. In some embodiments, the second bonding dielectric 102h includes silicon oxide. In some embodiments, the second bonding dielectric 102h is bonded with the first bonding dielectric 101h by fusion bonding, oxide to oxide bonding or any other suitable bonding techniques.

In some embodiments, the second bonding pad 102i is surrounded by and at least partially exposed through the second bonding dielectric 102h. In some embodiments, the second bonding pad 102i is disposed on the first bonding pad 101i. In some embodiments, the second bonding pad 102i is at least partially exposed through the second bonding dielectric 102h and configured to receive an external interconnect structure. In some embodiments, the second bonding pad 102i includes conductive material such as copper, silver or the like. In some embodiments, the second bonding pad 102i is bonded with the first bonding pad 101i by metal to metal bonding, direct bonding or any other suitable bonding techniques. In some embodiments, the second bonding pad 102i is vertically aligned with the first bonding pad 101i.

In some embodiments, the second dielectric 102d is disposed over the second bonding dielectric 102h. In some embodiments, the second dielectric 102d includes dielectric material such as polymer, polyimide, polybenzoxazole (PBO) or the like. In some embodiments, the second dielectric 102d includes several dielectric layers stacking over each other. In some embodiments, the dielectric layers includes same material or different materials. In some embodiments, the second dielectric 102d is interlayer dielectric (ILD).

In some embodiments, the second interconnect structure 101e is disposed within the second dielectric 102d. In some embodiments, the second interconnect structure 101e is disposed over the second bonding dielectric 102h. In some embodiments, the second interconnect structure 102e is an electrical routing within the second die structure 102. In some embodiments, the second bonding pad 102i is electrically connected with the second interconnect structure 101e. In some embodiments, the second bonding pad 102i extends through the second dielectric 102h to electrically connect to the second interconnect structure 102e. In some embodiments, the second interconnect structure 102e includes conductive material such as copper, silver or the like.

In some embodiments, the second interconnect structure 102e includes a second pad portion 102f and a second via portion 102g coupled with the second pad portion 102f. In some embodiments, the second via portion 102g extends vertically within the second dielectric 102d. In some embodiments, the second pad portion 102f extends laterally within the second dielectric 102d. In some embodiments, the second pad portion 102f is at least partially exposed through the second dielectric 102d. In some embodiments, the second pad portion 102f and the second via portion 102g include conductive material such as copper, silver or the like.

In some embodiments, the second substrate 102a includes semiconductive material such as silicon, germanium, gallium, arsenic, or a combination thereof. In some embodiments, the second substrate 102a is a semiconductor wafer. In some embodiments, the second substrate 102a is a silicon substrate. In some embodiments, the second interconnect structure 102e is electrically connected to a circuitry or an electrical component on or in the second substrate 102a. In some embodiments, the second interconnect structure 102e extends between the second substrate 102a and the second bonding dielectric 102h. In some embodiments, the second pad portion 102f is coupled with a circuitry or an electrical component on or in the second substrate 102a. In some embodiments, a thickness of the second substrate 102a is substantially greater than 3 um. In some embodiments, the thickness of the second substrate 102a is substantially greater than 10 um.

In some embodiments, the first substrate 101a includes a third surface 102b and a fourth surface 102c opposite to the third surface 102b. In some embodiments, the third surface 102b is a front side or an active side that several electrical components are disposed thereon. In some embodiments, a device 102j such as transistor, capacitor, diode or the like is disposed in the second substrate 102a and adjacent to the third surface 102b. In some embodiments, an isolation member 102k such as shallow trench isolation (STI) is disposed adjacent to the device 102j and within the second substrate 102a. In some embodiments, the fourth surface 102c is a back side or an inactive side that electrical component disposed thereon is absent.

In some embodiments, the dielectric member 103 is disposed over the second die structure 102. In some embodiments, the dielectric member 103 is disposed over the fourth surface 102c of the second substrate 102a. In some embodiments, the dielectric member 103 is a single layer or multiple layers structure. In some embodiments, the dielectric member 103 includes a first layer 103a, a second layer 103b over the first layer 103, a third layer 103c over the second layer 103b, and a fourth layer 103d over the third layer 103.

In some embodiments, the first layer 103a has a thickness of about 20 angstrom (A). In some embodiments, the first layer 103a is a thin oxide film. In some embodiments, the second layer 103b is configured to repair a surface of the second substrate 102a. In some embodiments, the third layer 103c is configured to prevent moisture. In some embodiments, the second layer 103b and the third layer 103c include high k (high dielectric constant) material such as hafnium dioxide, aluminum dioxide or the like. In some embodiments, the fourth layer 103d includes undoped silicate glass (USG), oxide or the like.

In some embodiments, a thickness of the fourth layer 103d is substantially greater than a thickness of the third layer 103c. In some embodiments, the thickness of the fourth layer 103d is substantially greater than a thickness of the second layer 103b. In some embodiments, a thickness of the first layer 103a is substantially less than the thickness of the second layer 103b. In some embodiments, the thickness of the first layer 103a is substantially less than the thickness of the third layer 103c. In some embodiments, the thickness of the first layer 103a is substantially less than the thickness of the fourth layer 103d.

In some embodiments, the conductive via 104 extends through and is surrounded by the dielectric member 103, the second substrate 102a and the isolation member 102k. In some embodiments, the conductive via 104 extends at least partially through the second dielectric 102d. In some embodiments, the conductive via 104 is coupled with the pad portion 102f of the second interconnect structure 102e. In some embodiments, the conductive via 104 includes conductive material such as copper, silver or the like. In some embodiments, a height of the conductive via 104 is substantially greater than 3 um. In some embodiments, the conductive via 104 is a backside through silicon via (BTSV).

In some embodiments, the conductive via 104 is surrounded by a spacer 105. In some embodiments, the spacer 105 extends through the dielectric member 103 and partially through the second substrate 102a. In some embodiments, the spacer 105 extends from and contacts the isolation member 102k. In some embodiments, the spacer 105 is surrounded by the dielectric member 103 and the second substrate 102a. In some embodiments, the spacer 105 is a single liner or multiple liners structure. In some embodiments, the spacer 105 is partially extended into the isolation member 102k. In some embodiments, the spacer 105 includes dielectric material such as oxide, nitride or the like. In some embodiments, the spacer 105 includes a first liner 105a and a second liner 105b surrounded by the first liner 105a. In some embodiments, the first liner 105a includes oxide, and the second liner 105b includes nitride. In some embodiments, the first liner 105a and the second liner 105b are partially extended into the isolation member 102k.

In some embodiments, the conductive member 106 is disposed over the dielectric member 103 and at least partially in contact with the conductive via 104. In some embodiments, the conductive member 106 is in contact with the fourth layer 103d of the dielectric member 103, the first liner 105a and the second liner 105b of the spacer 105. In some embodiments, the conductive member 106 includes conductive material such as copper, silver or the like. In some embodiments, a first interface between the conductive via 104 and the conductive member 106 is substantially coplanar with a second interface between the conductive member 106 and the dielectric member 103. In some embodiments, the second interface is between the conductive member 106 and the fourth layer 103d of the dielectric member 103.

In some embodiments, a third interface between the conductive member 106 and the spacer 105 is substantially coplanar with the first interface and the second interface. In some embodiments, the third interface includes an interface between the conductive member 106 and the first liner 105a of the spacer 105, and an interface between the conductive member 106 and the second liner 105b of the spacer 105. In some embodiments, the third interface is disposed between and coupled with the first interface and the second interface.

In some embodiments, a first outer surface 106a of the conductive member 106 contacting the dielectric member 103, the spacer 105 and the conductive via 104 is substantially planar. In some embodiments, a top surface 105c of the spacer 105 is substantially coplanar with the first outer surface 106a of the conductive member 106. In some embodiments, the first outer surface 106a extends along the dielectric member 103, the spacer 105 and the conductive via 104. In some embodiments, the first outer surface 106a of the conductive member 106 is in direct contact with a top surface 104a of the conductive via 104 exposed through the spacer 105 and the dielectric member 103. In some embodiments, the first outer surface 106a is a flat and planar surface.

In some embodiments, a passivation 107 is disposed over the dielectric member 103 and the conductive member 106. In some embodiments, the passivation 107 is disposed over the dielectric member 103 and covers at least a portion of the conductive member 106. In some embodiments, the passivation 107 is in contact with the dielectric member 103. In some embodiments, the passivation 107 includes dielectric material such as silicon oxide, silicon nitride, silicon carbide, silicon oxynitride or the like. In some embodiments, a fourth interface between the passivation 107 and the conductive member 106 is substantially planar. In some embodiments, the fourth interface is substantially parallel to the first interface and the second interface. In some embodiments, the passivation 107 includes a fifth layer 107a and a sixth layer 107b over the fifth layer 107a. In some embodiments, the fifth layer 107a includes oxide, and the sixth layer 107b includes nitride. In some embodiments, the fifth layer 107a is in contact with the fourth layer 103d.

In some embodiments, the first outer surface 106a of the conductive member 106 and an interface between the passivation 107 and the dielectric member 103 are at a same level. In some embodiments, the first outer surface 106a of the conductive member 106 and the interface between fifth layer 107a of the passivation 107 and fourth layer 103d of the dielectric member 103 are at a same level. In some embodiments, a second outer surface 106b of the conductive member 106 contacting the passivation 107 and disposed above the first outer surface 106a is substantially planar. In some embodiments, the first outer surface 106a is substantially parallel to the second outer surface 106b.

In some embodiments, a conductive bump 108 is disposed on the conductive member 106 and is protruded from the passivation 107. In some embodiments, the conductive bump 108 is configured to mount on another die structure and electrically connect with an external interconnect structure or another die structure. In some embodiments, the conductive bump 108 is ball grid array (BGA) balls, controlled collapse chip connection (C4) bumps, microbumps, pillars or the like. In some embodiments, the conductive bump 108 includes metals such as lead, tin copper, gold, nickel, etc. or metal alloy such as combination of lead, tin copper, gold, nickel, etc. In some embodiments, instead of the conductive bump 108, a testing probe (not shown) is disposed on the conductive member 106 to undergo a testing for the semiconductor structure 100.

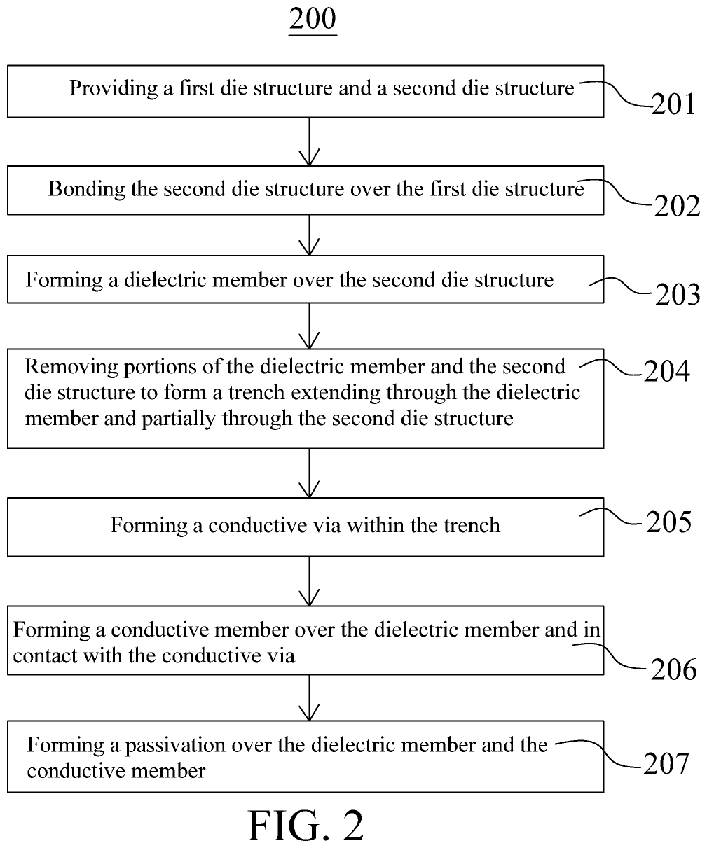

In the present disclosure, a method of manufacturing a semiconductor structure 100 is also disclosed. In some embodiments, the semiconductor structure 100 is formed by a method 200. The method 200 includes a number of operations and the description and illustration are not deemed as a limitation as the sequence of the operations. FIG. 2 is an embodiment of the method 200 of manufacturing the semiconductor structure 100. The method 200 includes a number of operations (201, 202, 203, 204, 205, 206 and 207).

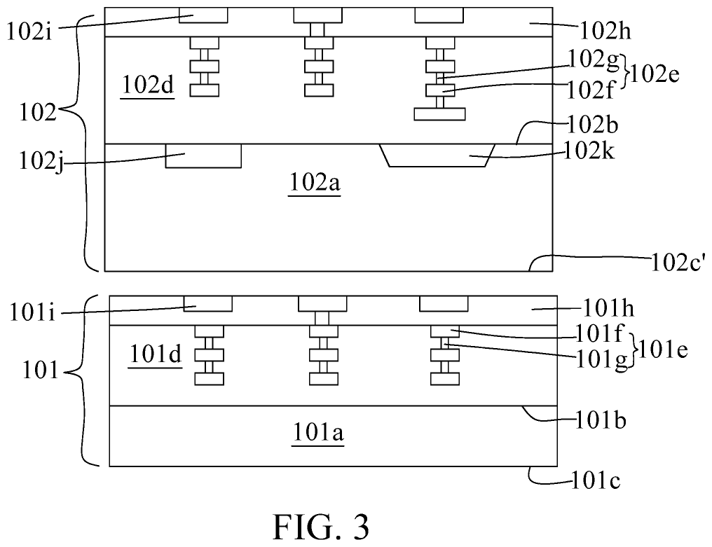

In operation 201, a first die structure 101 and a second die structure 102 are provided as shown in FIG. 3. In some embodiments, the first die structure 101 has similar configurations as the first die structure 101 illustrated in FIG. 1 and discussed above. In some embodiments, the first die structure 101 is disposed over a carrier substrate (not shown). In some embodiments, the carrier substrate is configured to temporarily support the first die structure 101. In some embodiments, the carrier substrate is a blank glass, ceramic, silicon or the like. In some embodiments, the second die structure 102 has similar configurations as the second die structure 102 illustrated in FIG. 1 and discussed above, except a thickness of the second substrate 102a of the second die structure 102 as shown in FIG. 3 is substantially greater than a thickness of the first substrate 101a of the first die structure 101, and the second substrate 102a has an untreated second surface 102c′ as shown in FIG. 3.

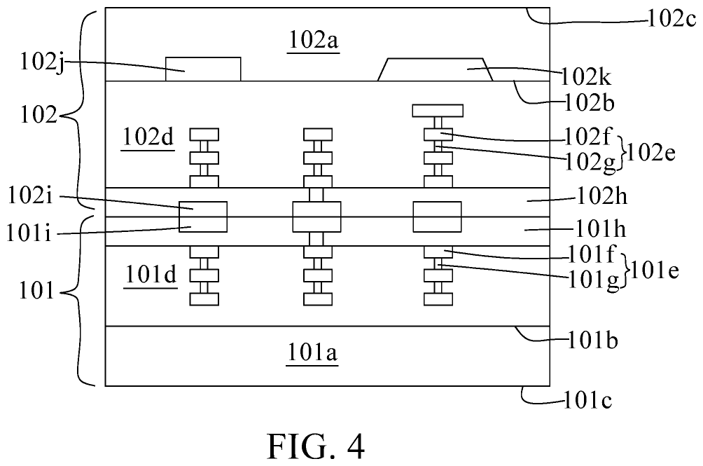

In operation 202, the second die structure 102 is bonded over the first die structure 101 as shown in FIG. 4. The second die structure 102 is flipped and then bonded with the first die structure 101. In some embodiments, the second die structure 102 is bonded with the first die structure 101 by bonding the first bonding dielectric 101h with the second bonding dielectric 102h and bonding the first bonding pad 101i with the second bonding pad 102i. In some embodiments, the second die structure 102 is bonded with the first die structure 101 by hybrid bonding or any other suitable operations. In some embodiments, after the bonding, the thickness of the second substrate 102a is reduced by grinding, etching, chemical mechanical polishing (CMP) or any other suitable operations to form the second surface 102c from the untreated second surface 102c′ (shown in FIG. 3).

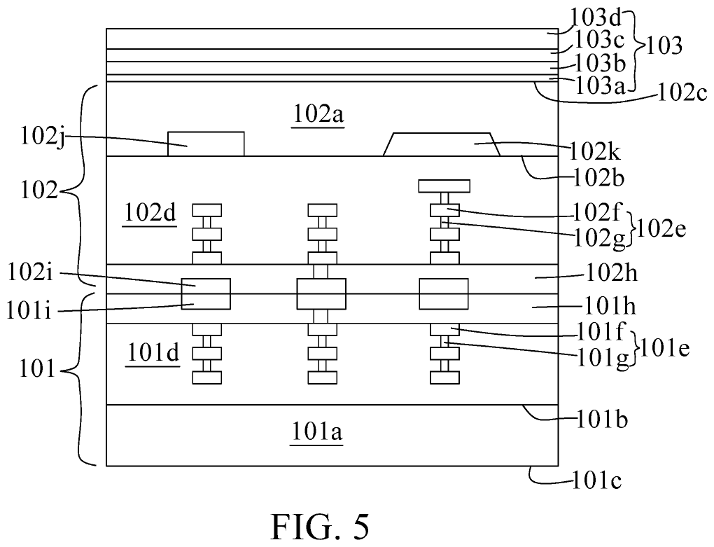

In operation 203, a dielectric member 103 is formed over the second substrate 102a as shown in FIG. 5. In some embodiments, the dielectric member 103 has similar configurations as the dielectric member 103 illustrated in FIG. 1 and discussed above. In some embodiments, the dielectric member 103 is formed by sequentially disposing the first layer 103a, the second layer 103b, the third layer 103c and the fourth layer 103d by deposition, chemical vapor deposition (CVD) or any other suitable operations. Since the thickness of the second substrate 102a is reduced by grinding, the second layer 103b is disposed to repair a ground surface of the second substrate 102a. In some embodiments, the first layer 103a, the second layer 103b, the third layer 103c and the fourth layer 103d have similar configurations as the first layer 103a, the second layer 103b, the third layer 103c and the fourth layer 103d respectively illustrated in FIG. 1 and discussed above.

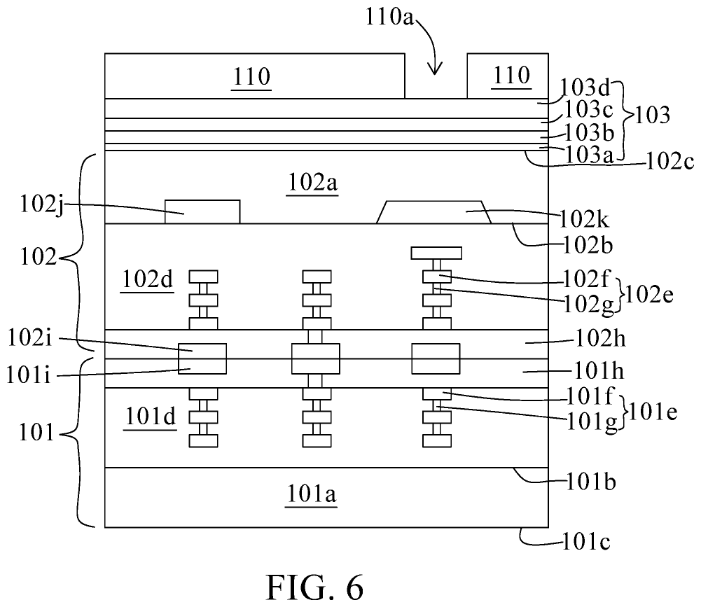

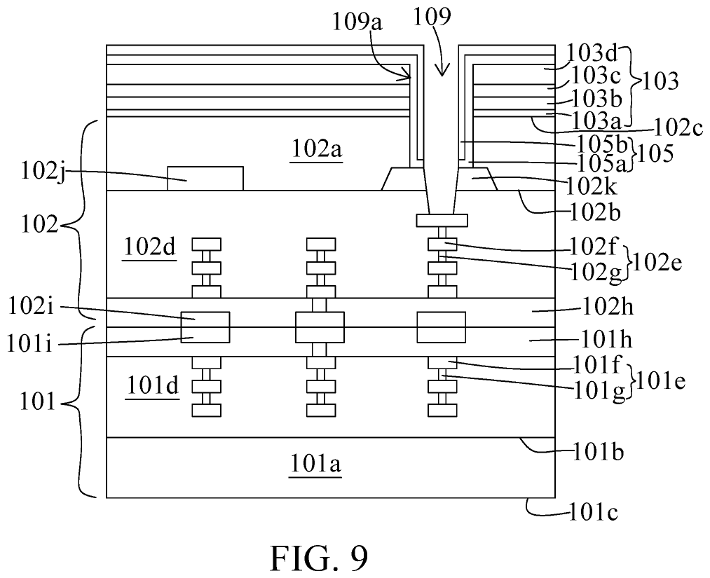

In operation 204, portions of the dielectric member 103 and the second die structure 102 are removed to form a trench 109 extending through the dielectric member 103 and partially through the second die structure 102 as shown in FIG. 9. In some embodiments, after the formation of the dielectric member 103 (the operation 203) and prior to the formation of the trench 109, a photoresist material is disposed over the dielectric member 103 and then a portion of the photoresist material is removed to form a patterned photoresist layer 110 having a first opening 110a extending through the patterned photoresist layer 110 as shown in FIG. 6. In some embodiments, the photoresist material is disposed by spin coating or any other suitable operations, and the portion of the photoresist material is removed by etching or any other suitable operations. In some embodiments, at least a portion of the dielectric member 103 or the fourth layer 103d of the dielectric member 103 is exposed through the patterned photoresist layer 110 as shown in FIG. 6.

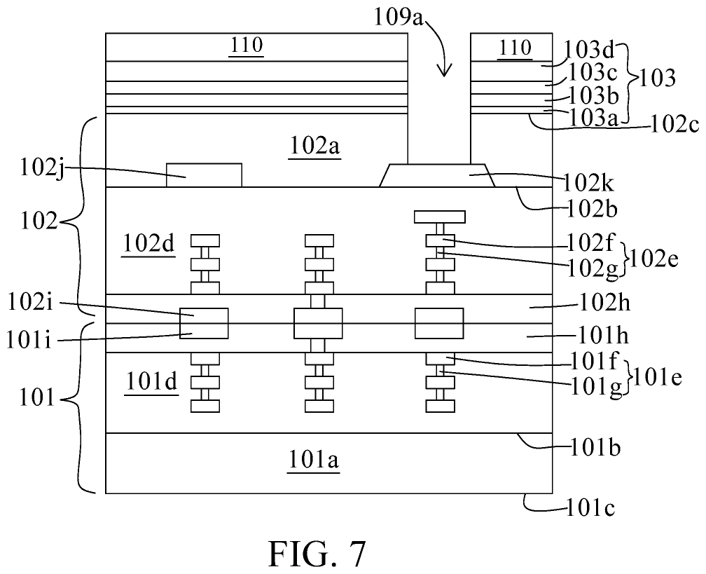

In some embodiments, after the formation of the patterned photoresist layer 110 over the dielectric member 103 as shown in FIG. 6, portions of the dielectric member 103 and the second substrate 102a exposed through the patterned photoresist layer 110 are removed to form a partial portion 109a as shown in FIG. 7. In some embodiments, the portions of the dielectric member 103 and the second substrate 102a are removed by etching or any other suitable operations. In some embodiments, the removal would stop at the isolation member 102k because the removal has a high etching selectivity of silicon of the second substrate 102a, so that at least a portion of the isolation member 102k is exposed through the second substrate 102a, the dielectric member 103 and the patterned photoresist layer 110. In some embodiments, the isolation member 102k has similar configurations as the isolation member 102k as illustrated in FIG. 1 and discussed above. In some embodiments, portions of the patterned photoresist layer 110 is consumed during the removal of the portions of the dielectric member 103 and the second substrate 102a, such that a thickness of the patterned photoresist layer 110 before the removal as shown in FIG. 6 is substantially greater than a thickness of the patterned photoresist layer 110 after the removal as shown in FIG. 7.

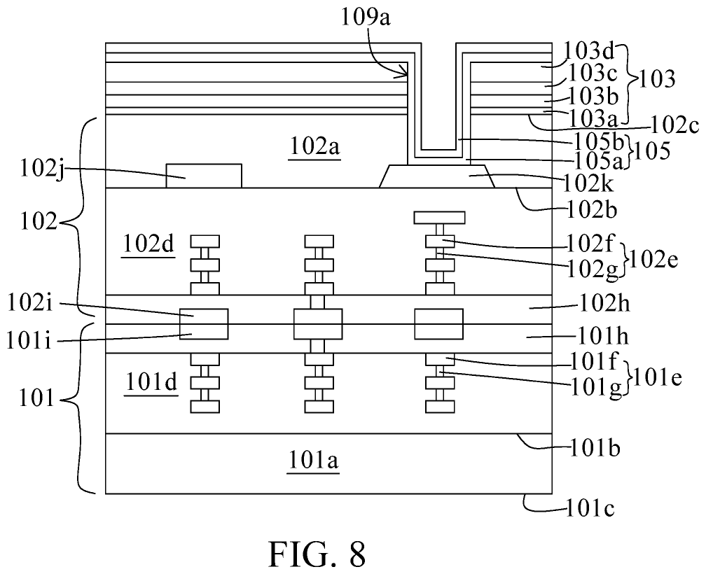

In some embodiments, after the formation of the partial trench 109a, the patterned photoresist layer 110 is removed by etching, ashing or any other suitable operations as shown in FIG. 8. In some embodiments, after the removal of the patterned photoresist layer 110, a spacer 105 is formed within the partial trench 109a as shown in FIG. 8. In some embodiments, the spacer 105 is formed by sequentially disposing a first liner 105a over the dielectric member 103 and within the partial trench 109a, and disposing a second liner 105b over the first liner 105b as shown in FIG. 8. In some embodiments, the first liner 105a is disposed conformal to the partial trench 109a and on the isolation member 102k. In some embodiments, the spacer 105 is configured to protect a sidewall of the partial trench 109a. In some embodiments, the first liner 105a and the second liner 105b are disposed by deposition or any other suitable operations. In some embodiments, the spacer 105, the first liner 105a and the second liner 105b have similar configurations as the spacer 105, the first liner 105a and the second liner 105b illustrated in FIG. 1 and discussed above.

In some embodiments, after the formation of the spacer 105 as shown in FIG. 8, portions of the spacer 105 on the isolation member 102k, portions of the isolation member 102k covered by the spacer 105 and portions of the second dielectric 102d under the isolation member 122k are removed to form the trench 109 as shown in FIG. 9. In some embodiments, the removal is performed by blanket etching or any other suitable operations. In some embodiments, the removal would stop at the second interconnect structure 102e or the pad portion 102f of the second interconnect structure 102e, so that at least a portion of the second interconnect structure 102e or a portion of the pad portion 102f is exposed through the trench 109. In some embodiments, the trench 109 extends through the dielectric member 103, the second substrate 102a and the isolation member 102k, extends partially through the second dielectric 102d, and surrounded by the spacer 105.

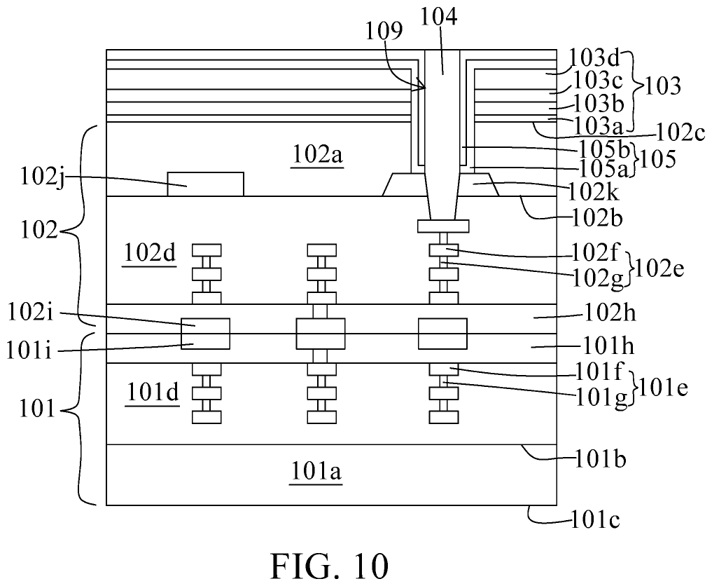

In operation 205, a conductive via 104 is formed as shown in FIG. 10 after the formation of the trench 109 as shown in FIG. 9. In some embodiments, the conductive via 104 is formed by disposing a conductive material within the trench 109. In some embodiments, the conductive material is disposed by electroplating or any other suitable operations. In some embodiments, the conductive via 104 is coupled with or electrically connected to the second interconnect structure 102e. In some embodiments, the conductive via 104 is surrounded by the spacer 105, the isolation member 102k and the second dielectric 102d. In some embodiments, the conductive via 104 has similar configuration as the conductive via 104 illustrated in FIG. 1 and discussed above.

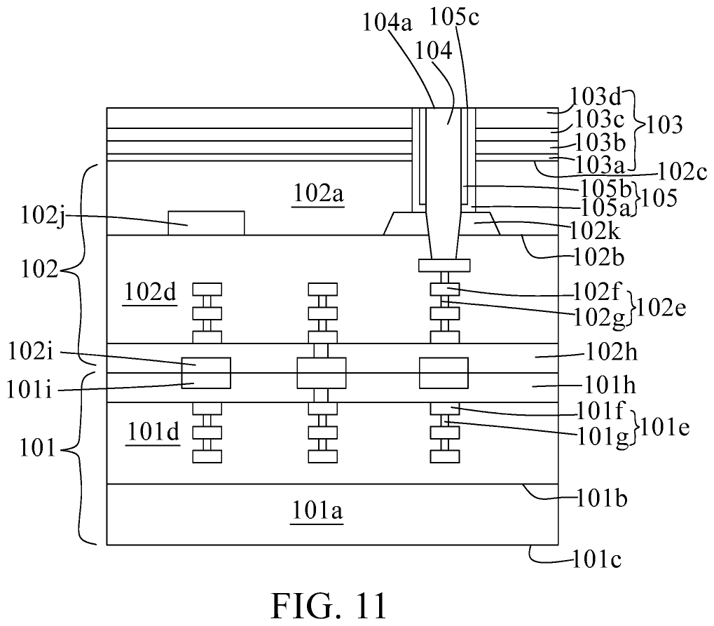

In some embodiments, after the disposing of the conductive material within the trench 109, portions of the spacer 105 and the conductive material disposed over the dielectric member 103 are removed by etching, planarization, chemical mechanical polishing (CMP) or any other suitable operations as shown in FIG. 11. In some embodiments, a top surface 104a of the conductive via 104 and a top surface 105c of the spacer 105 are formed after the removal as shown in FIG. 11. In some embodiments, the top surface 104a of the conductive via 104, the top surface 105c of the spacer 105 and a top surface of the dielectric member 103 are substantially coplanar.

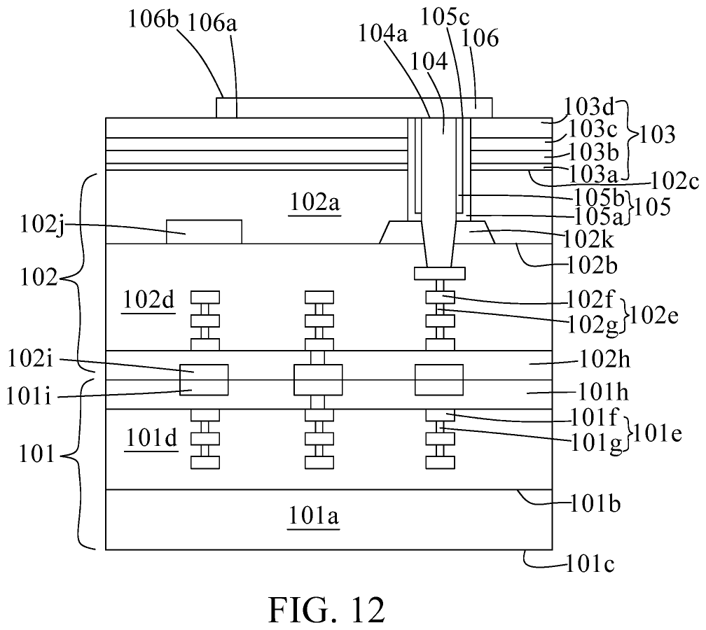

In operation 206, a conductive member 106 is formed over the dielectric member 103 and in contact with the conductive via 104 as shown in FIG. 12. In some embodiments, the formation of the conductive member 106 is immediately after the formation of the conductive via 104. In some embodiments, the conductive member 106 is formed by disposing a conductive material over the dielectric member 103, covering a portion of the conductive material, and removing an exposed portion of the conductive material. In some embodiments, the conductive material is disposed by deposition, sputtering, electroplating or any other suitable operations. In some embodiments, the exposed portion of the conductive material is removed by etching or any other suitable operations. In some embodiments, the conductive member 106 has similar configuration as the conductive member 106 illustrated in FIG. 1 and discussed above.

In some embodiments, the first outer surface 106a of the conductive member 106 is a flat and planar surface. In some embodiments, the second outer surface 106b of the conductive member 106 is in contact with the top surface 104a of the conductive via 104 and the top surface of the dielectric member 103. In some embodiments, the second outer surface 106b of the conductive member 106, the top surface 104a of the conductive via 104 and the top surface 105c of the spacer 105 are substantially coplanar. In some embodiments, the formation of the conductive member includes forming a first interface between the conductive via 104 and the conductive member 106 and a second interface between the conductive member 106 and the dielectric member 103. The first interface is substantially coplanar with the second interface. In some embodiments, the first interface and the second interface are formed simultaneously. In some embodiments, a third interface between the conductive member 106 and the spacer 105 is substantially coplanar with the first interface and the second interface.

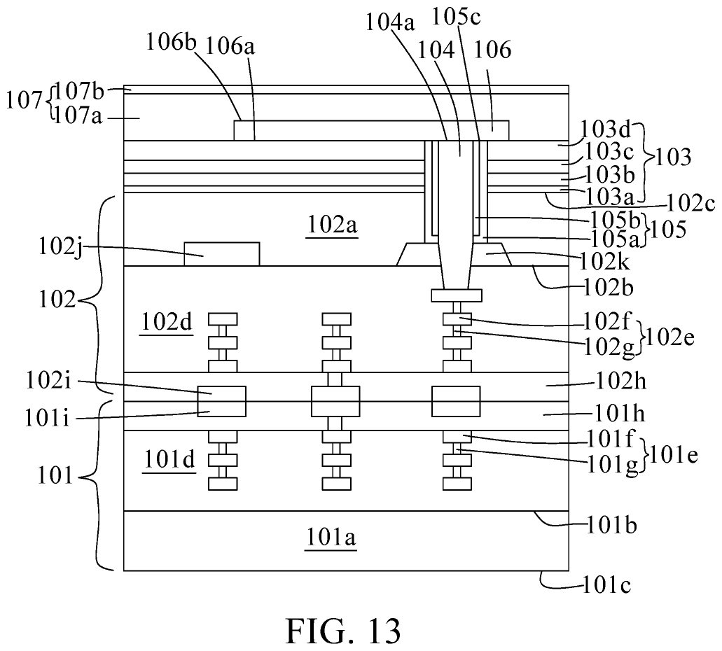

In operation 207, a passivation 107 is formed over the dielectric member 103 and the conductive member 106 as shown in FIG. 13. In some embodiments, the passivation 107 is formed by sequentially disposing a fifth layer 107a over the dielectric member 103 and covering the conductive member 106, and the disposing a sixth layer 107b over the fifth layer 107a. In some embodiments, the passivation 107, the fifth layer 107a and the sixth layer 107b have similar configurations as the passivation 107, the fifth layer 107a and the sixth layer 107b illustrated in FIG. 1 and discussed above. In some embodiments, the fifth layer 107a and the sixth layer 107b are disposed by deposition or any other suitable operations. In some embodiments, a fourth interface between the passivation 107 and the conductive member 106 is substantially planar.

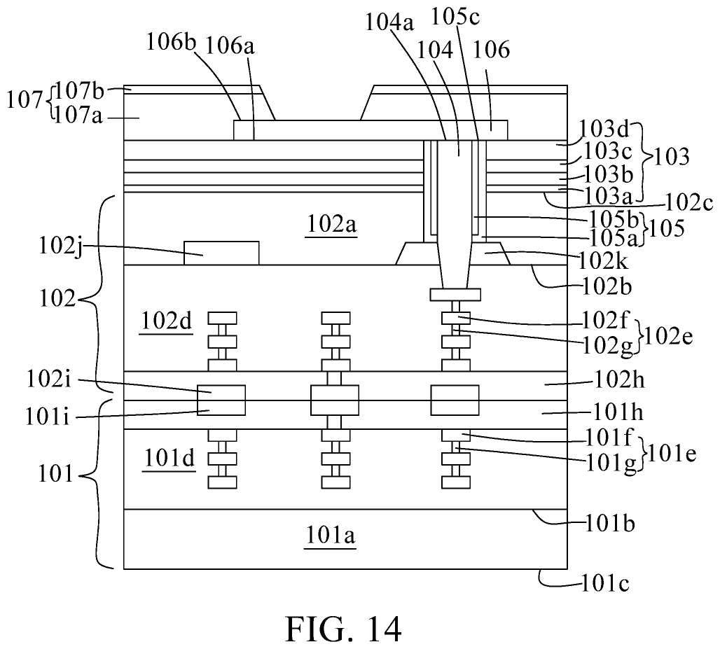

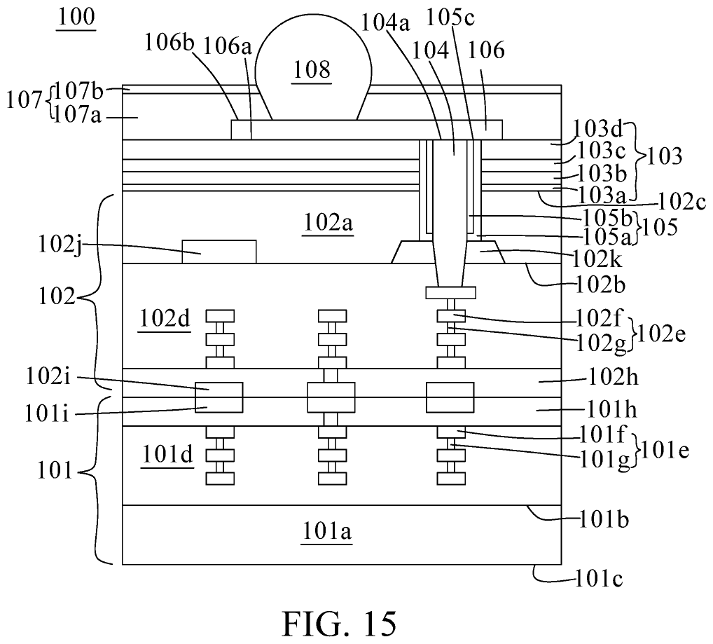

In some embodiments, after the formation of the passivation 107 as shown in FIG. 13, a portion of the passivation 107 is removed to expose at least a portion of the conductive member 106 as shown in FIG. 14. In some embodiments, the portion of the passivation 107 is removed by covering a portion of the conductive member 106 and removing an exposed portion of the conductive member 106 by etching or any other suitable operations. In some embodiments, after the removal as shown in FIG. 14, a conductive bump 108 is formed on the exposed portion of the conductive member 106 as shown in FIG. 15. In some embodiments, the conductive bump 108 is formed by solder pasting, electroplating or any other suitable operations. In some embodiments, the semiconductor structure 100 is formed as illustrated in FIG. 1 and discussed above. In some embodiments, instead of forming the conductive bump 108, a testing of the semiconductor structure 100 is performed by disposing a testing probe on the conductive member 106.

One aspect of this disclosure relates to a semiconductor structure. The semiconductor structure includes a first die structure including a first substrate, a first bonding dielectric disposed over the first substrate, and a first bonding pad surrounded by the first bonding dielectric; a second die structure including a second substrate, an isolation member extending into the second substrate, a second bonding dielectric bonded with the first bonding dielectric, and a second bonding pad surrounded by the second bonding dielectric and bonded with the first bonding pad; a dielectric member disposed over the second die structure; a conductive via extending through the dielectric member, the second substrate and the isolation member; and a conductive member disposed over the dielectric member and at least partially in contact with the conductive via, wherein a first interface between the conductive via and the conductive member is substantially coplanar with a second interface between the conductive member and the dielectric member.

In some embodiments, the conductive via is surrounded by a spacer extending between the conductive member and the isolation member, extending through the second substrate and the dielectric member, and contacting the isolation member. In some embodiments, the spacer is in contact with the conductive member. In some embodiments, a third interface between the conductive member and the spacer is substantially coplanar with the first interface and the second interface. In some embodiments, the third interface is disposed between and coupled with the first interface and the second interface. In some embodiments, the first die structure includes a first dielectric disposed between the first substrate and the first bonding dielectric, and a first interconnect structure within the first dielectric, the first interconnect structure is coupled with the first bonding pad. In some embodiments, the second die structure includes a second dielectric disposed between the second substrate and the second bonding dielectric, and a second interconnect structure within the second dielectric. In some embodiments, the conductive via extends at least partially through the second dielectric and coupled with the second interconnect structure. In some embodiments, the second interconnect structure is coupled with the second bonding pad. In some embodiments, the semiconductor structure further includes a passivation disposed over the dielectric member and the conductive member, wherein the conductive member is at least partially exposed through the passivation. In some embodiments, a fourth interface between the passivation and the conductive member is substantially planar. In some embodiments, the fourth interface is substantially parallel to the first interface and the second interface.

One aspect of this disclosure relates to a semiconductor structure. The semiconductor structure includes a first die structure; a second die structure bonded over the first die structure; a dielectric member disposed over the second die structure; a conductive via extending through the dielectric member and partially through the second die structure; a spacer surrounding the conductive via and extending through the dielectric member and partially through the second die structure; and a conductive member disposed over the dielectric member and coupled with the conductive via, wherein a first outer surface of the conductive member contacting the dielectric member, the spacer and the conductive via is substantially planar.

In some embodiments, the semiconductor structure further includes a passivation disposed over the dielectric member and covering at least a portion of the conductive member, wherein the first outer surface of the conductive member and an interface between the passivation and the dielectric member are at a same level. In some embodiments, the semiconductor structure further includes a conductive bump disposed over the conductive member and protruded from the passivation. In some embodiments, the semiconductor structure further includes a top surface of the spacer is substantially coplanar with the first outer surface of the conductive member. In some embodiments, a second outer surface of the conductive member contacting the passivation and disposed above the first outer surface is substantially planar. In some embodiments, the first outer surface is substantially parallel to the second outer surface.

An aspect of this disclosure relates to a method of manufacturing a semiconductor structure. The method includes providing a first die structure and a second die structure; bonding the second die structure over the first die structure; forming a dielectric member over the second die structure; removing portions of the dielectric member and the second die structure to form a trench extending through the dielectric member and partially through the second die structure; forming a conductive via within the trench; forming a conductive member over the dielectric member and in contact with the conductive via; and forming a passivation over the dielectric member and the conductive member, wherein the formation of the conductive member includes forming a first interface between the conductive via and the conductive member and a second interface between the conductive member and the dielectric member, the first interface is substantially coplanar with the second interface.

In some embodiments, the first interface and the second interface are formed simultaneously.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first die structure including a first substrate, a first bonding dielectric disposed over the first substrate, and a first bonding pad surrounded by the first bonding dielectric;
a second die structure including a second substrate, an isolation member extending into the second substrate, a second bonding dielectric bonded with the first bonding dielectric, and a second bonding pad surrounded by the second bonding dielectric and bonded with the first bonding pad;
a dielectric member disposed over the second die structure;
a conductive via extending through the dielectric member, the second substrate and the isolation member; and
a conductive member disposed over the dielectric member and at least partially in contact with the conductive via,
wherein a first interface between the conductive via and the conductive member is substantially coplanar with a second interface between the conductive member and the dielectric member.

2. The semiconductor structure of claim 1, wherein the conductive via is surrounded by a spacer extending between the conductive member and the isolation member, extending through the second substrate and the dielectric member, and contacting the isolation member.

3. The semiconductor structure of claim 2, wherein the spacer is in contact with the conductive member.

4. The semiconductor structure of claim 2, wherein a third interface between the conductive member and the spacer is substantially coplanar with the first interface and the second interface.

5. The semiconductor structure of claim 4, wherein the third interface is disposed between and coupled with the first interface and the second interface.

6. The semiconductor structure of claim 1, wherein the first die structure includes a first dielectric disposed between the first substrate and the first bonding dielectric, and a first interconnect structure within the first dielectric, the first interconnect structure is coupled with the first bonding pad.

7. The semiconductor structure of claim 1, wherein the second die structure includes a second dielectric disposed between the second substrate and the second bonding dielectric, and a second interconnect structure within the second dielectric.

8. The semiconductor structure of claim 7, wherein the conductive via extends at least partially through the second dielectric and coupled with the second interconnect structure.

9. The semiconductor structure of claim 7, wherein the second interconnect structure is coupled with the second bonding pad.

10. The semiconductor structure of claim 1, further comprising a passivation disposed over the dielectric member and the conductive member, wherein the conductive member is at least partially exposed through the passivation.

11. The semiconductor structure of claim 10, wherein a fourth interface between the passivation and the conductive member is substantially planar.

12. The semiconductor structure of claim 10, wherein the fourth interface is substantially parallel to the first interface and the second interface.

13. A semiconductor structure, comprising:
a first die structure;
a second die structure bonded over the first die structure;
a dielectric member disposed over the second die structure;
a conductive via extending through the dielectric member and partially through the second die structure;
a spacer surrounding the conductive via and extending through the dielectric member and partially through the second die structure; and
a conductive member disposed over the dielectric member and coupled with the conductive via,
wherein a first outer surface of the conductive member contacting the dielectric member, the spacer and the conductive via is substantially planar.

14. The semiconductor structure of claim 13, further comprising a passivation disposed over the dielectric member and covering at least a portion of the conductive member, wherein the first outer surface of the conductive member and an interface between the passivation and the dielectric member are at a same level.

15. The semiconductor structure of claim 14, further comprising a conductive bump disposed over the conductive member and protruded from the passivation.

16. The semiconductor structure of claim 13, wherein a top surface of the spacer is substantially coplanar with the first outer surface of the conductive member.

17. The semiconductor structure of claim 13, wherein a second outer surface of the conductive member contacting the passivation and disposed above the first outer surface is substantially planar.

18. The semiconductor structure of claim 17, wherein the first outer surface is substantially parallel to the second outer surface.

19. A method of manufacturing a semiconductor structure, comprising:
providing a first die structure and a second die structure;
bonding the second die structure over the first die structure;
forming a dielectric member over the second die structure;
removing portions of the dielectric member and the second die structure to form a trench extending through the dielectric member and partially through the second die structure;
forming a conductive via within the trench;
forming a conductive member over the dielectric member and in contact with the conductive via; and
forming a passivation over the dielectric member and the conductive member, wherein the formation of the conductive member includes forming a first interface between the conductive via and the conductive member and a second interface between the conductive member and the dielectric member, the first interface is substantially coplanar with the second interface.

20. The method of claim 19, wherein the first interface and the second interface are formed simultaneously.
